(19) United States
(12) Patent Application Publication
(10) Pub. No.: US 2014/0119146 A1
(43) Pub. Date: May 1, 2014

(54) Clock Gated Storage Array

(71) Applicant: APPLE INC., Cupertino, CA (US)

(72) Inventor: Brian P. Lilly, San Francisco, CA (US)

(73) Assignee: APPLE INC., Cupertino, CA (US)

(21) Appl. No.: 13/663,946

(22) Filed: Oct. 30, 2012

(51) Int. Cl. G11C 5/14

(52) U.S. Cl. 365/227

(57) ABSTRACT

A storage array and a method of operating the same are disclosed. A storage array includes a number of clocked storage circuits arranged in rows and columns. The storage array is subdivided into a number of grids each including a subset of clocked storage circuits and also includes a number of clock gating circuits, each of which is coupled to provide a clock signal to the clocked storage circuits of a corresponding subset. During an access of the storage array (i.e. a read or a write), one of the clock gating circuits is configured to provide the clock signal to the clocked storage circuits of its correspondingly coupled subset. The remaining clock gating circuits are configured to inhibit the clock signal from being provided to the flop circuits of their respectively coupled subsets.

### BACKGROUND

1. Technical Field

This disclosure is directed to integrated circuits, and more particularly, clock gating for circuits within an integrated circuit.

2. Description of the Related Art

Integrated circuits often times include on-board storage arrays for storing data used by various functional units. Such storage arrays may be used for various functions. For example, storage arrays may be used in various processors for storing information regarding the ordering of various transactions.

The implementation of storage arrays may be accomplished using various types of storage circuits. Some storage arrays may be implemented using flop circuits (e.g., flip-flops). Such flop circuits may operate according to a clock signal. In storage arrays implemented using clocked flop circuits, the clock signal may be provided to each of the flop circuits of the storage array.

### SUMMARY

A storage array and a method of operating the same are disclosed. In one embodiment, a storage array includes a number of clocked storage circuits arranged in rows and columns. Each of the clocked storage circuits is located at the intersection of a particular one of the rows and a particular one of the columns. The storage array is subdivided into a number of grids each including a subset of clocked storage circuits. The storage circuit also includes a number of clock gating circuits, each of which is coupled to provide a clock signal to the clocked storage circuits of a corresponding subset. During an access of the storage array (i.e. a read or a write), one of the clock gating circuits is configured to provide the clock signal to the clocked storage circuits of its correspondingly coupled subset. The remaining clock gating circuits are configured to inhibit the clock signal from being provided to the flop circuits of their respectively coupled subsets.

In one embodiment, a storage array includes a number of flop circuits arranged in M rows and M columns. The flop circuits of the storage array is subdivided into a number of N×N grids of flop circuits, wherein M and N are integer values greater than one, and wherein M is greater than N. Each of a number of clock gating circuits is coupled to provide a gated clock signal to the flop circuits of a particular one of the N×N grids. During an access the storage array, a control circuit is configured to cause one of the clock gating circuits to provide a clock signal to the flop circuits of a corresponding one of the N×N grids. The control circuit is further configured to cause the remaining ones of the clock gating circuits to inhibit the clock signal from being provided to their respectively coupled ones of the N×N grids. When the storage array is not being accessed, the control circuit is configured to cause each of the clock gating circuits to inhibit the clock signal from being provided to their respectively coupled N×N grids.

### BRIEF DESCRIPTION OF THE DRAWINGS

The following detailed description makes reference to the accompanying drawings, which are now briefly described.

FIG. 1 is a block diagram of one embodiment of an IC.

FIG. 2 is a diagram illustrating one embodiment of a storage array.

FIG. 3 is a flow diagram illustrating one embodiment of a method for operating a storage array.

FIG. 4 is a block diagram of one embodiment of an exemplary system.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include”, “including”, and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six interpretation for that unit/circuit/component.

### DETAILED DESCRIPTION OF EMBODIMENTS

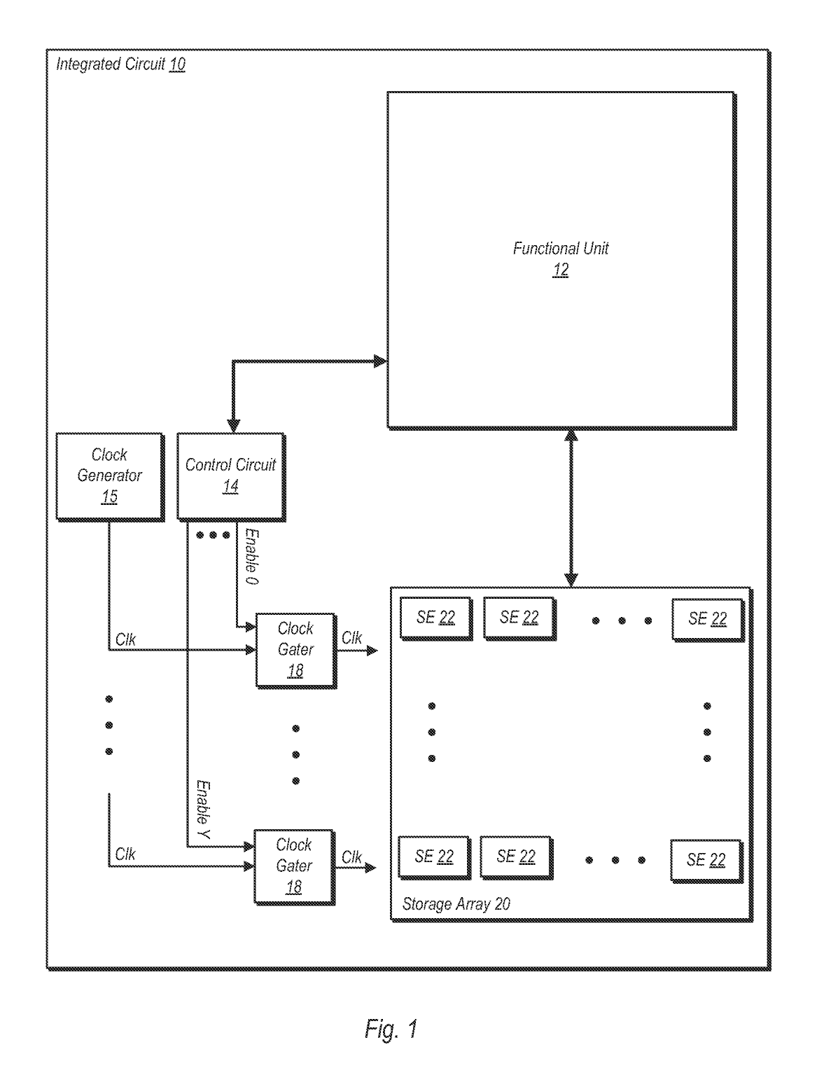

Turning now to FIG. 1, a block diagram of one embodiment of an integrated circuit (IC) is illustrated. In the embodiment shown, IC 10 includes a functional unit 12 coupled to a storage array 20. Functional unit 12 may perform one or more intended functions of IC 10. In performing the intended functions of IC 10, functional unit 12 may utilize storage array 20 for the storage of data. Storage array 20 may be one of a number of different types of storage units such as an ordering queue for determining and tracking an order of transaction involving functional unit 12. In the embodiment shown, storage array 20 includes a number of clocked storage elements 22, which may be implemented as flip-flops, latches, or generally, as clocked flop circuits. The storage elements 22 are arranged in rows and columns, with each individual storage element being at an intersection of one row and one column. In some embodiments, the number of rows and number of columns may be equal. In other embodiments, the number of rows and number of columns may be different.

In general, storage array 20 may include A rows and B columns, wherein A and B are integer values greater than one. Furthermore, A may be equal to B in some embodiments, while these values may be different in others.

IC 10 in the embodiment shown includes a clock generator 15 configured to generate a clock signal that may be provided to the storage elements 22 of storage array 20. IC 10 also includes a number of clock gaters 18, each of which is coupled to receive the clock signal from clock generator 15. Each of the clock gaters 15 is coupled to provide the clock signal to a selected subset of storage elements 22. When a given clock gater 15 receives an asserted enable signal, it may allow the clock signal to propagate to its respectively coupled storage elements 22. Otherwise, when the enable signal provided to a given clock gater 18 is not asserted, the clock signal as output therefrom may be inhibited and thus not provided to the respectively coupled storage elements 22.

Assertion and de-assertion of the enable signals may be performed under the direction of control circuit 14. In the embodiment shown, there are Y clock gaters 18, where Y is an integer value greater than one. Correspondingly, the storage elements 22 of storage array 20 may be subdivided into a total of Y subsets. Accordingly, control circuit 14 is configured to provide Y different enable signals, one for each of the Y clock gaters 18. In one embodiment, control circuit 14 may be configured to assert one enable signal during a given access to storage array 20, while holding the remaining enable signals in a de-asserted state. When storage array 20 is not being accessed, control circuit 14 may hold all of the enable signals as de-asserted. Thus, for a given write cycle or read cycle, access to storage array 20 may be restricted to storage elements 22 of a given subset. Moreover, during a given write cycle or read cycle, only those storage elements 22 in the given subset may receive an active clock signal, while the clock signal may be inhibited for storage elements in each of the remaining subsets.

As noted above, storage array 20 may be implemented using various numbers of storage elements arranged in various numbers of rows and columns. In one exemplary embodiment, storage array 20 includes eight rows and eight columns (M=8) for a total of 64 storage elements 22. Moreover, storage array 20 may be subdivided into four subsets of 16 elements, wherein each subset is a 4×4 (N=4) grid of storage elements 22. Such an embodiment would thus include four clock gaters 18, one each for each subset. During an access to storage array 20, only one of the four clock gaters 18 would be enabled, while the other three clock gaters 18 would be disabled. During times when storage array 20 is not being accessed, control circuit 14 would disable each of the clock gaters 18, and thus no clock signal would be provided to any of the storage elements 22.

It is noted that while this exemplary array is arranged in a square grid, embodiments that are not arranged as square grids are possible and contemplated. Similarly, while subsets may be arranged in square grids, embodiments in which the subsets are arranged in a different manner are also possible and contemplated.

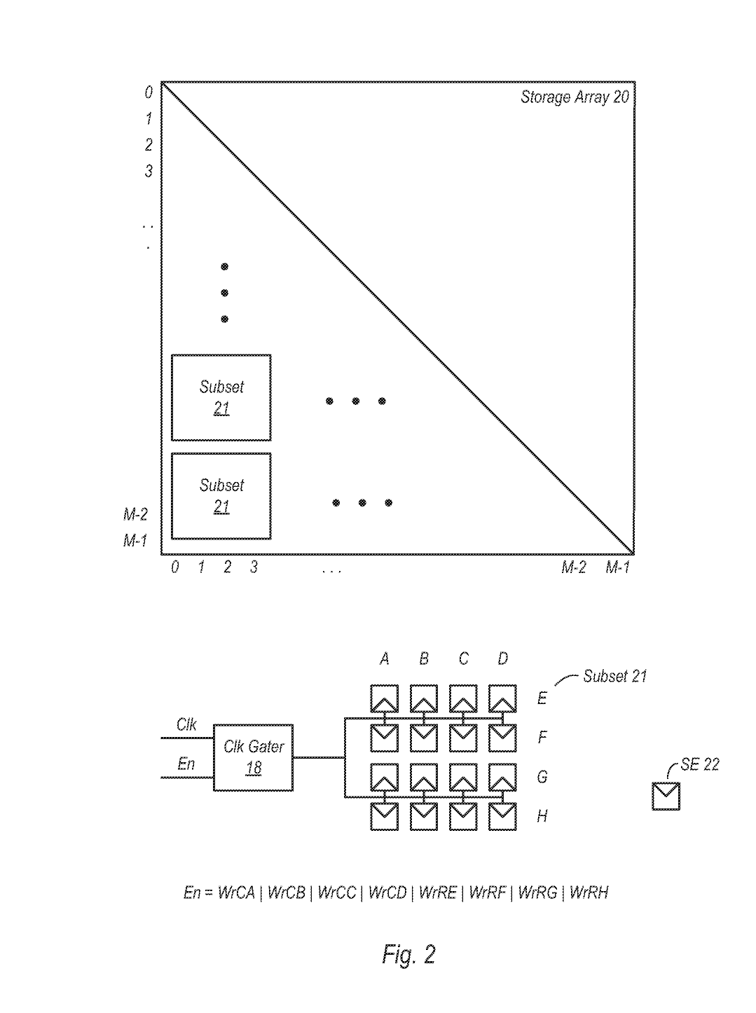

FIG. 2 is a diagram illustrating one embodiment of a storage array. In the embodiment shown, storage array 20 is an M×M storage array, having M rows and M columns of storage elements 22. Storage array 20 is subdivided into a number of subsets 21 of storage elements 22 (implemented here as flip-flops). Each subset 21 in the embodiment shown is arranged as an N×N subset (where N=4 in this particular example).

In the embodiment shown, an exemplary 4×4 subset is shown as being coupled to a respective clock gater 18. The 4×4 subset includes columns A, B, C, and D, and also includes rows E, F, G, and H. The clock gater 18 is coupled to receive a clock signal and an enable signal, and is configured to allow the clock signal to pass when the enable signal is asserted. When the enable signal is not asserted, the clock signal is inhibited by clock gater 18.

The conditions for asserting the enable signal during a write to one or more storage elements 22 of subset 21 are shown in the equation listed in FIG. 2. In this example, the conditions for asserting the enable signal is an OR of a write to any storage element 22 in any of columns A, B, C, or D, or a write to any storage element 22 in any of rows E, F, G, or H. It is noted that multiple storage elements 22 within a subset 21 may be written to during a given write cycle. It is further noted that similar conditions for asserting the enable signal during a read also apply. That is, the enable signal may be asserted for a ready of a storage element 22 of any of columns A, B, C, or D, or any of rows E, F, G, or H. Similarly, multiple storage elements 22 may be read during a given read cycle.

As noted above, control circuit 18 shown in FIG. 1 is configured to assert only one enable signal at a given time. Thus, when one or more storage elements 22 of the illustrated subset 21 are targeted for a read or a write operation, the enable signal to the corresponding clock gater 18 is asserted, while enable signals provided to remaining ones of the clock gaters 18 may be de-asserted. When one or more storage elements 22. in another subset 21 than that illustrated in FIG. 2 are targeted for a read or a write, the enable signal to the illustrated clock gater 18 may be de-asserted. When no storage elements 22 within storage array 20 are targeted for a read or write operation, all enable signals may be de-asserted, and thus no clock signal is provided to any storage element 22 (and thus to any subset 21).

It is noted that in the exemplary storage array 20 of FIG. 2, a diagonal line is shown descending from the upper left corner to the lower right corner. This line is to illustrate the fact that some storage arrays may include a property of symmetry, and thus the number of storage elements 22 may be reduced by one half. This in turn results in a lower number of subsets 21, a lower number of clock gaters 18. However, the property of symmetry does not apply to all possible embodiments of a storage array 20.

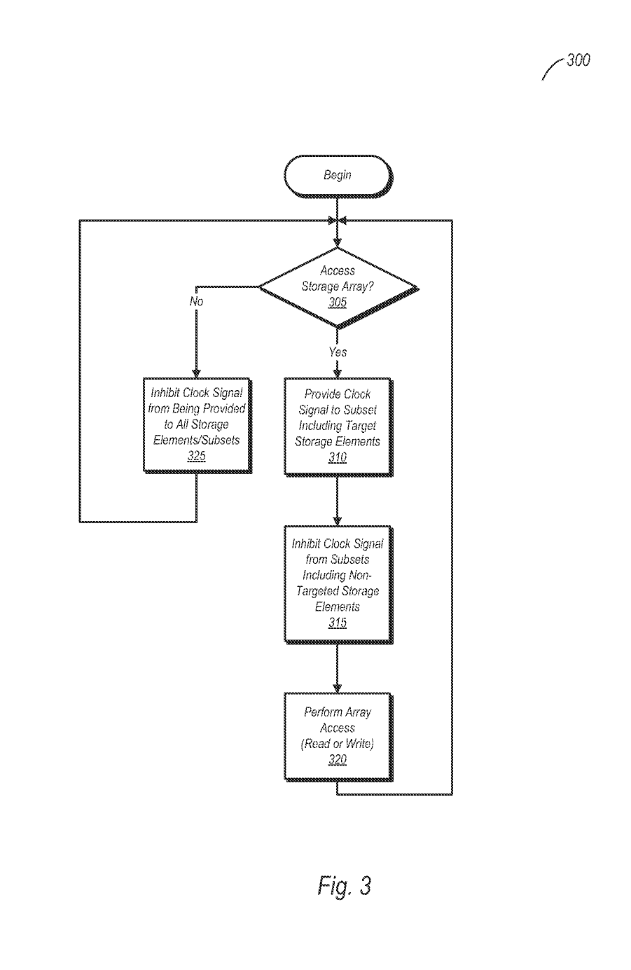

FIG. 3 is a flow diagram illustrating one embodiment of a method for operating a storage array. Method 300 may be used with any of the embodiments of an IC and/or storage array discussed above, as well as with embodiments not explicitly discussed herein.

Method 300 begins with the determination of whether a storage array is to be accessed during a given operational cycle (block 305). If no access (read or write) of the storage array is to occur during the given operational cycle (block 305, no), then a control circuit may cause a number of clock gates to inhibit a clock signal from being provided to all storage elements in the storage array (block 325). Since the storage array may be subdivided into subsets of storage elements, clock gaters corresponding to each subset may be provided, and each may be disable when no access to the array is in progress. The method then returns to block 305 for the next operational cycle.

If the storage array is to be access (block 305, yes), then the control circuit may enable one of the clock gaters to pass the clock signal to a subset that includes the targeted storage elements (block 310). Targeted storage elements may be defined as those storage elements that are to be written to or read from during the access of the storage array. While the clock signal is provided to the subset of storage elements that includes the targeted storage element(s), the control circuit may cause the remaining clock gaters to inhibit the clock signal from being provided to their respective subsets (block 315). The array may then be accessed by performing a read from or a write to the targeted storage elements (block 320). After the access is complete, the method returns to block 305 for the next operational cycle.

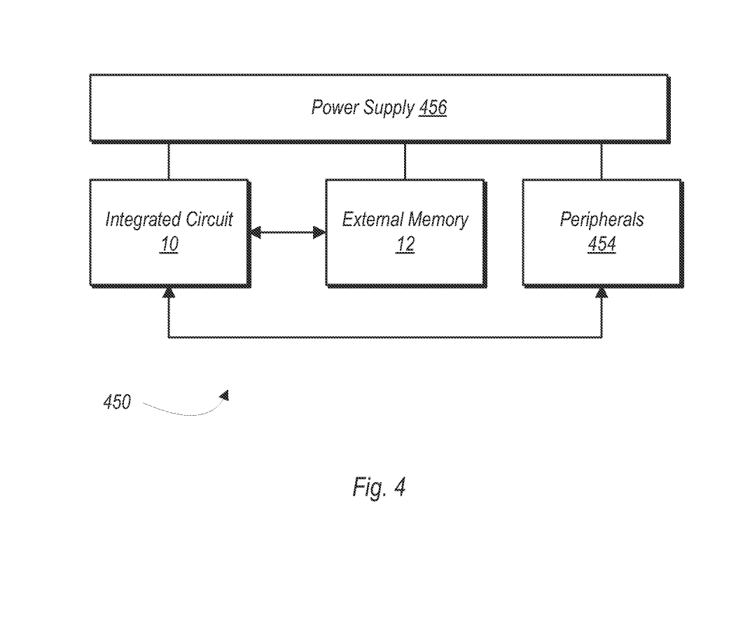

Turning next to FIG. 4, a block diagram of one embodiment of a system 350 is shown. In the illustrated embodiment, the system 450 includes at least one instance of the integrated circuit 10 coupled to external memory 12 (e.g. the memory 12A-12B in

FIG. 1). The integrated circuit 10 is coupled to one or more peripherals 454 and the external memory 12. A power supply 456 is also provided which supplies the supply voltages to the integrated circuit 10 as well as one or more supply voltages to the memory 12 and/or the peripherals 454. In some embodiments, more than one instance of the integrated circuit 10 may be included (and more than one external memory 12 may be included as well).

The peripherals 454 may include any desired circuitry, depending on the type of system 450. For example, in one embodiment, the system 450 may be a mobile device (e.g. personal digital assistant (PDA), smart phone, etc.) and the peripherals 454 may include devices for various types of wireless communication, such as WiFi, Bluetooth, cellular, global positioning system, etc. The peripherals 454 may also include additional storage, including RAM storage, solid state storage, or disk storage. The peripherals 454 may include user interface devices such as a display screen, including touch display screens or multitouch display screens, keyboard or other input devices, microphones, speakers, etc. In other embodiments, the system 450 may be any type of computing system (e.g. desktop personal computer, laptop, workstation, net top etc.).

Numerous variations and modifications will become apparent to those skilled in the art once the above disclosure is fully appreciated. It is intended that the following claims be interpreted to embrace all such variations and modifications.

What is claimed is:

1. A circuit comprising:
a storage array having a plurality of having a plurality of clocked storage elements arranged in rows and columns, wherein each storage element is located at an intersection of one of the rows and one of the columns;
a plurality of clock gating circuits each coupled to provide a gated clock signal to a corresponding one of a plurality of subsets of storage elements, wherein each subset is arranged in an A×B grid.

2. The circuit as recited in claim 1, further comprising a control circuit coupled to each of the plurality of clock gating circuits, wherein, during an access to the storage array, the control circuit is configured to cause one of the plurality of clock gating circuits to provide a respective clock signal to its respectively coupled subset of storage elements and further configured to cause remaining ones of the plurality of clock gating circuits to inhibit a respective clock signal from being provided to their respective subsets of storage elements.

3. The circuit as recited in claim 2, wherein the control circuit is further configured to cause each of the clock gating circuits to inhibit a clock signal from being provided to their respectively coupled subset of storage elements when the storage array is not being accessed.

4. The circuit as recited in claim 1, wherein A and B are each integer values greater than one, and wherein A is equal to B.

5. The circuit as recited in claim 1, wherein A and B are each integer values greater than one, and wherein A is not equal to B.

6. A method comprising:
accessing a storage array having a plurality of clocked storage elements arranged in rows and columns and divided into subsets, wherein each subset include an M×N grid of storage elements;
providing a clock signal to storage elements of a first subset that includes the storage elements being accessed; and
inhibiting a clock signal from being provided to each storage element of a subset that does not include the storage elements being accessed.

7. The method as recited in claim 6, wherein M and N are integer values greater than one, and wherein M and N are equal.

8. The method as recited in claim 6, wherein storage elements of each of the subsets is coupled to a corresponding unique one of a plurality of clock gating circuits, and wherein the method further comprises a first one of the plurality of clock gating circuits providing a clock signal to each storage element of the first subset during said accessing.

9. The method as recited in claim 8, further comprising a control circuit causing the first one of the clock gating circuits to provide the clock signal to each storage element of the first subset during said accessing, and further comprising each remaining one of clock gating circuits from inhibiting the clock signal from being provided to storage elements of their corresponding subsets.

10. The method as recited in claim 9, further comprising the control circuit causing each of the clock gating circuits to inhibit the clock signal from being provided to each of the plurality of storage elements when the storage array is not being accessed.

11. A storage array comprising:
a plurality of clocked storage elements arranged in M rows and M columns, and wherein each of the plurality of storage elements is located at an intersection of a corresponding one of the M rows and a corresponding one of the M columns;
a plurality of clock gaters, wherein each clock gater is coupled to provide a gated clock signal to a corresponding unique N×N grid of storage elements, wherein each of the plurality of clock gaters is configured to operate independently of each of the other ones of the plurality of clock gaters.

12. The storage array as recited in claim 11, wherein M and N are integer values greater than one, and wherein M is greater than N.

13. The storage array as recited in claim 11, further comprising a control circuit configured to, during a write to the storage array, cause one of the plurality of clock gaters to provide the clock signal to a particular one of the N×N grids including the storage elements to which data is to be written, and further cause remaining ones of the plurality of clock gaters to inhibit the clock signal from being provided to their respectively coupled N×N grids.

14. The storage array as recited in claim 13, wherein the control circuit is further configured to, during a read of the storage array, cause one of the plurality of clock gaters to provide the clock signal to a particular one of the N×N grids including the storage elements from which data is to be read, and further cause remaining ones of the plurality of clock gaters to inhibit the clock signal from being provided to their respectively coupled N×N grids.

15. The storage array as recited in claim 14, wherein the control circuit is further configured to cause each of the plurality of clock gaters to inhibit the clock signal from being provided to their respectively coupled N×N grids when neither a read from nor a write to the storage array is being performed.

16. A method comprising:
providing a clock signal to an N×N grid of flop circuits during an access of a storage unit having a plurality of flop circuits arranged in M rows and M columns, wherein the plurality of flop circuits includes the N×N grid of flop circuits; and
inhibiting a clock signal from being provided to each of the remaining flop circuits of the storage unit not included in the N×N grid.

17. The method as recited in claim 16, wherein the accessing the storage unit comprises writing data to one or more flop circuits of the N×N grid.

18. The method as recited in claim 16, wherein accessing the storage unit comprises reading data from one or more flop circuit of the N×N grid.

19. The method as recited in claim 16, wherein M and N are integer values greater than one, and wherein M is greater than N.

20. The method as recited in claim 16, further comprising inhibiting the clock signal from being provided to any of the flop circuits of the storage unit when the storage unit is not being accessed.

21. An integrated circuit comprising:
a storage unit having a plurality of flop circuits arranged in a plurality of N×N grids of flop circuits;
a plurality of clock gating circuits, wherein each of the plurality of clock gating circuits is coupled to provide a gated clock signal to a corresponding one of the plurality of N×N grids;
a functional unit configured to write data to the storage unit and read data from the storage unit; and
a control unit coupled to each of the plurality of clock gating circuits, wherein the control unit is configured to, during an access, cause one of the plurality of clock gating circuits to provide the clock signal to the flop circuit of a selected one of the N×N grids, and further configured to cause the remaining clock gating circuits to inhibit the clock signal from being provided to their respectively coupled N×N grids.

22. The integrated circuit as recited in claim 21, wherein the control unit is configured which of the clock gating circuits is configured to provide the clock signal to the flop circuits of its corresponding N×N grid based on an information provided by the functional unit.

23. The integrated circuit as recited in claim 21, wherein the control unit is configured to cause each of the plurality of clock gating circuits to inhibit the clock signal from being provided to flop circuits of their respectively coupled N×N grids when the functional unit is not accessing the storage unit.

24. The integrated circuit as recited in claim 21, wherein the storage unit is arranged in M rows and M columns of flop circuits, wherein each of the flop circuits is located at an intersection of one of the M rows and one of the M columns.

25. The integrated circuit as recited in claim 24, wherein M and N are integer values greater than one, and wherein M is greater than N.
